(19) United States
(12) Patent Application Publication
(10) Pub. No.: US 2017/0110291 A1
(43) Pub. Date: Apr. 20, 2017

(54) SUBSTRATE TREATMENT APPARATUS

(71) Applicant: Samsung Electronics Co., Ltd., Suwon-si (KR)

(72) Inventors: Tae-Hwa KIM, Hwaseong-si (KR); Byungbok KANG, Hwaseong-si (KR); Chanhoon PARK, Osan-si (KR); Jaehyun LEE, Yongin-si (KR); SungHyup KIM, Hwaseong-si (KR); Jaeick HONG, Seoul (KR)

(73) Assignee: Samsung Electronics Co., Ltd., Suwon-si (KR)

(21) Appl. No.: 15/204,038

(22) Filed: Jul. 7, 2016

(30) Foreign Application Priority Data
Oct. 15, 2015 (KR) 10-2015-0144114

(51) Int. Cl. H01J 37/32

(52) U.S. Cl. CPC H01J 37/32449; H01J 37/32834; H01J 37/32082; H01J 2237/006; H01J 2237/334

(57) ABSTRACT

A substrate treatment apparatus may include one or more of a process chamber, a gas supply assembly that may supply one or more gases into the process chamber, a gas exhaust assembly that may exhaust gases from the process chamber, and a gas injector assembly connected to the gas exhaust assembly independently of the process chamber. The gas injector assembly may supply a control gas into the gas exhaust assembly. The apparatus may include a gas injection control device configured to adjustably control the supply of control gas. The gas inject control device may measure an internal pressure of the process chamber and control the supply of control gas based on the internal pressure. The apparatus may include a diffuser that couples the gas injector assembly to the gas exhaust assembly and is configured to diffuse the control gas supplied from the gas injector assembly into the gas exhaust assembly.

### CROSS-REFERENCE TO RELATED APPLICATIONS

This U.S. non-provisional patent application claims priority under 35 U.S.C. §119 to Korean Patent Application No. 10-2015-0144114, filed on Oct. 15, 2015, in the Korean intellectual Property Office, the entire contents of which are hereby incorporated by reference.

### BACKGROUND OF THE INVENTION

The present disclosure relates to substrate treatment apparatuses, and in particular, to substrate treatment apparatuses configured to supply one or more additional control gases into an exhausting line of the substrate treatment apparatus and to control an internal pressure of a process chamber of the substrate treatment apparatus.

In some cases, semiconductor devices may be fabricated using a plurality of unit processes, including a deposition process or an etching process, an ion implantation process, and a cleaning process. In some cases, the deposition and etching processes may be performed using a plasma reaction. For a three-dimensional semiconductor device (e.g., V-NAND Flash memory), there is an increasing demand for a method capable of forming patterns with a high aspect, and a gas-pulsing etching process is studied to meet the demand. In addition, a reduction in size of patterns leads to an increase in the number of process steps.

### SUMMARY

Some example embodiments of the inventive concepts provide a substrate treatment apparatus configured to supply an additional gas into an exhausting line and to control an internal pressure of a chamber.

Some example embodiments of the inventive concepts provide a substrate treatment apparatus including a diffusion part, allowing a control gas to be diffused when the control gas is supplied into the exhausting line through an injection unit.

According to some example embodiments of the inventive concepts, a substrate treatment apparatus may include a process chamber; a gas supply assembly; a gas exhaust assembly; an exhaust valve; a gas injector assembly; and a gas injection control device. The gas supply assembly may be configured to supply a first gas and a second gas into the process chamber such that the first gas is supplied into the process chamber at a uniform first flow rate, and the second gas is supplied into the process chamber at a second flow rate. The second flow rate may vary according to a first pulse wave. The first pulse wave may have a particular time period. The gas exhaust assembly may be configured to exhaust the first and second gases from the process chamber. The gas exhaust assembly may include an exhausting line coupled to the process chamber, the exhausting line being configured to discharge gas from the process chamber, and a pump coupled to the exhausting line, the pump being configured to induce gas flow from the process chamber through the exhausting line. The exhaust valve may be coupled to the exhausting line and may be configured to control a flow rate of gas into the exhausting line from the process chamber, the exhaust valve including a fixed opening extent. The gas injector assembly may be coupled to the exhausting line between the exhaust valve and the pump, the gas injector assembly being configured to supply a third gas into the exhausting line. The gas injection control device may be configured to measure an internal pressure of the process chamber, and control the injection unit to supply the third gas into the exhausting line at a third flow rate based on the measured internal pressure of the process chamber, the third flow rate varying according to a second pulse wave, the second pulse wave having the particular time period.

The gas injection control device may include a chamber pressure sensor configured to measure the internal pressure of the process chamber and a controller device configured to process the measured internal pressure of the process chamber to determine the third flow rate and control the injection unit to supply the third gas into the exhausting line according to the third flow rate.

The second pulse wave may be phase-shifted from the first pulse wave according to a phase difference, the phase difference being approximately one-half of the time period.

The second pulse wave may be phase-shifted from the first pulse wave by approximately 180 degrees.

The gas injection control device may be configured to control the third flow rate such that the internal pressure of the process chamber ranges from about 15 mTorr to about 25 mTorr.

The gas injector assembly may include a third gas reservoir configured to hold the third gas and a third gas supply line that couples the third gas reservoir to the exhausting line. The apparatus may further include a control valve coupled to the third gas supply line, the control valve being configured to control an opening extent of the third gas supply line. The gas injection control device may be configured to control the third gas reservoir and the control valve to adjustably control the third flow rate.

The first gas may include one of argon or helium. The second gas may include one or more fluorocarbons. The third gas may be a non-reactive gas including one of argon, nitrogen, or helium.

The apparatus may further include a diffuser between the exhausting line and the gas injector assembly. The diffuser may be configured to diffuse the third gas supplied into the exhausting line from the as injector assembly.

According to some example embodiments of the inventive concepts, a substrate treatment apparatus may include a process chamber, a gas supply assembly, a gas exhaust assembly, an exhaust valve, a gas injector assembly, and a diffuser. The gas supply assembly may be configured to supply a first gas and a second gas into the process chamber. The gas exhaust assembly may be configured to exhaust the first and second gases from the process chamber. The gas exhaust assembly may include an exhausting line coupled to the process chamber, the exhausting line being configured to discharge gas from the process chamber, and a pump coupled to the exhausting line, the pump being configured to induce gas flow from the process chamber through the exhausting line. The exhaust valve may be coupled to the exhausting line. The exhaust valve may be configured to control a flow rate of gas into the exhausting line from the process chamber, the exhaust valve including a fixed opening extent. The gas injector assembly may be coupled to the exhausting line between the exhaust valve and the pump. The gas injector assembly may be configured to supply a third gas into the exhausting line. The diffuser may be configured to diffuse the third gas supplied into the exhausting line from the gas injector assembly.

The diffuser may include an outer shell coupled to the gas injector assembly; and an inner shell, the inner shell having a smaller diameter than the outer shell, the inner shell including a plurality of first holes, the inner shell being configured to diffuse the third gas into the exhausting line through the plurality of first holes.

The diffuser further may include a middle shell between the outer shell and the inner shell, the middle shell including a plurality of second holes.

A quantity of the first holes may be greater than a quantity of the second holes.

Each of the second holes may include a greater diameter than the first holes.

The apparatus of claim 9 may further comprise a plurality of gas injector assemblies, the gas injector assemblies being spaced apart according to a uniform distance.

The exhaust valve may be configured to be opened between about 7% of a fully-open position to about 20% of the fully-open position.

According to some example embodiments of the inventive concepts, an apparatus may comprise a diffuser configured to couple to a gas line and diffuse a gas into the gas line. The diffuser may include an outer shell including at least one gas supply line, the outer shell being configured to couple with a gas supply source through the at least one gas supply line; and an inner shell at least partially enclosed by the outer shell, the inner shell being configured to couple with the gas line, the inner shell including a plurality of first holes, the inner shell being configured to diffuse the third gas into the exhausting line through the plurality of first holes.

The diffuser may further include a middle shell between the outer shell and the inner shell, the middle shell including a plurality of second holes.

A quantity of the first holes may be greater than a quantity of the second holes.

Each of the second holes may include a greater diameter than the first holes.

The outer shell may include a plurality of gas supply lines. The outer shell may be configured to couple with at least one gas supply source through the plurality of gas supply lines.

### BRIEF DESCRIPTION OF THE DRAWINGS

The foregoing and other features of inventive concepts will be apparent from the more particular description of non-limiting embodiments of inventive concepts, as illustrated in the accompanying drawings in which like reference characters refer to like parts throughout the different views. The drawings are not necessarily to scale, emphasis instead being placed upon illustrating principles of inventive concepts. In the drawings:

FIG. 1 is a diagram schematically illustrating a substrate treatment apparatus according to some example embodiments of the inventive concepts.

FIG. 2 is a cross-sectional view illustrating an exhaust valve according to some example embodiments of the inventive concepts.

FIG. 3 is a partial perspective view illustrating a diffuser of FIG. 1.

FIG. 4 is a sectional view illustrating a diffuser of FIG. 1.

FIG. 5 is a graph showing a variation in flow rate of gases supplied into a chamber and an exhausting line, according to some example embodiments of the inventive concepts.

FIG. 6 is a graph showing the times taken to stabilize internal pressures of a chamber and an exhausting line, according to some example embodiments of the inventive concepts.

FIG. 7 is a flow chart illustrating a method of controlling an internal pressure of a chamber, according to some example embodiments of the inventive concepts.

FIG. 8 is a diagram schematically illustrating a substrate treatment apparatus according to some example embodiments of the inventive concepts.

FIG. 9 is a perspective view illustrating a diffuser of FIG. 8.

FIG. 10 is a sectional view illustrating a diffuser of FIG. 8.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference characters and/or numerals in the drawings denote like elements, and thus their description may not be repeated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). As used herein the term “and/or” includes any and all combinations of one or more of the associated listed items.

It will be understood that, although the terms “first”, “second”, etc. may be used herein to describe various elements, components, regions, layers and/or sections. These elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the ten “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, hut do not preclude the presence or addition of one or more other features, integers, steps, operations, elements, components and/or groups thereof. Expressions such as “at least one of” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an etched region or an implanted region illustrated as a rectangle may have rounded or curved features. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Exemplary embodiments of aspects of the present inventive concepts explained and illustrated herein include their complementary counterparts. The same reference numerals or the same reference designators denote the same elements throughout the specification.

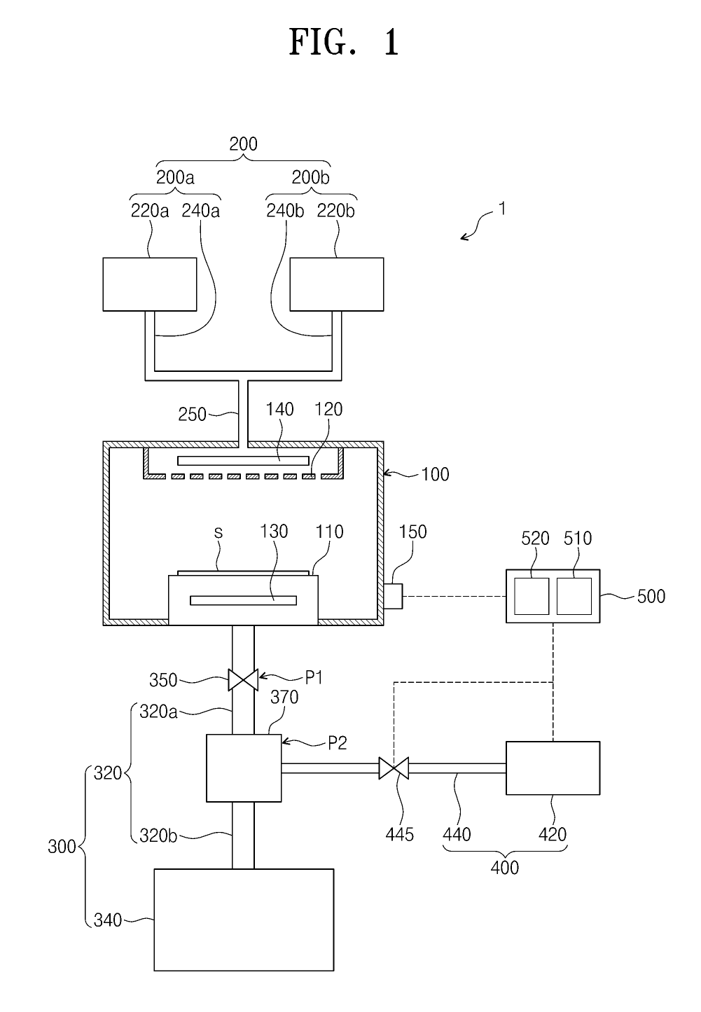

FIG. 1 is a diagram schematically illustrating a substrate treatment apparatus according to some example embodiments of the inventive concepts.

Referring to FIG. 1, a substrate treatment apparatus 1 may include one or more of a process chamber 100, a supplying unit 200 (also referred to a gas supply assembly 200), an exhaust unit 300 (also referred to as a gas exhaust assembly 300), an injection unit 400 (also referred to as a gas injector assembly 400), and a control unit 500 (also referred to as a gas injection control device 500).

The process chamber 100 may include an internal space that is isolated from the outside and is configured to perform a process on a substrate S. The substrate S may be disposed in the process chamber 100, and the process chamber 100 may be configured to allow the substrate S to be treated under vacuum condition. The process chamber 100 may include an electrostatic chuck 110, a shower head 120, a first electrode 130, a second electrode 140, and a chamber pressure sensor 150. The electrostatic chuck 110 may be disposed at a lower region of the process chamber 100. The electrostatic chuck 110 may be configured to hold or fasten the substrate S. The shower head 120 may be disposed at an upper region of the process chamber 100. The shower head 120 may be configured to inject a process gas supplied from the supplying unit 200 into the process chamber 100. The first electrode 130 may be disposed in the electrostatic chuck 110, and the second electrode 140 may be disposed in the shower head 120. However, the positions of the first and second electrodes 130 and 140 may not be limited thereto. As an example, both of the first and second electrodes 130 and 140 may be disposed in the lower region of the process chamber 100. Radio frequency (RF) power may be applied to at least one of the first and second electrodes 130 and 140. The RF power may be used to induce a plasma reaction from the process gas to be supplied into the process chamber 100. The chamber pressure sensor 150 may be configured to measure an internal pressure of the process chamber 100. The data of internal pressure measured by the chamber pressure sensor 150 may be transmitted to the control unit 500.

The supplying unit 200, also referred to herein as a gas supply assembly 200, may include a first supplying unit 200a, a second supplying unit 200b, and a main line 250. The first supplying unit 200a may include a first gas supplying part 220a, also referred to as a first gas reservoir 220a, in which a first gas is stored, and a first supplying line 240a, which is used to supply the first gas from the first gas supplying part 220a to the process chamber 100. The first gas may be a process gas. The first gas may be used in a process of etching the substrate S and may contain, for example, one of argon (Ar) or helium (He). The first supplying line 240a may be provided to connect the first gas supplying part 220a to the main line 250. The main line 250 may be referred to herein as the “main gas supply line.” The first supplying line 240a may be formed of or include at least one of materials (e.g., plastic, Teflon, or stainless steel) having high corrosion resistance with respect to the first gas.

The second supplying unit 200b may include a second gas supplying part 220b, also referred to herein as second gas reservoir 220b, in which a second gas is stored, and a second supplying line 240b, which is used to supply the second gas from the second gas supplying part 220b to the process chamber 100. The second gas may be used in the process of etching the substrate S. The second gas may be a process gas. The second gas may contain one or more fluorocarbons. For example, the second gas may be a gas containing carbon (C) and fluorine (F) (e.g., hexafluorobutadiene (C₄F₆)). The second supplying line 240b may be provided to connect the second gas supplying part 220b to the main line 250. The second supplying line 240b may be formed of or include at least one of materials (e.g., plastic, Teflon, or stainless steel) having high corrosion resistance with respect to the second gas.

The main line 250 may connect the first supplying line 240a and the second supplying line 240b to the process chamber 100. In other words, the first supplying line 240a and the second supplying line 240b may be connected to the process chamber 100 through the main line 250. The main line 250 may be used to deliver the first and second gases, which are respectively supplied from the first and second supplying lines 240a and 240b, to the process chamber 100.

The first gas and the second gas may be selected to exhibit different etching characteristics with respect to the substrate S. In some embodiments, the first supplying line 240a may have substantially the same diameter as the second supplying line 240b. In some example embodiments, the first and second supplying lines 240a and 240b may have diameters different from each other, in consideration of requirements in flow rate and/or pressure of the first and second gases. For example, in the case where a flow rate of the first gas is higher than that of the second gas, the first supplying line 240a may be provided to have a diameter greater than that of the second supplying line 240b.

The exhaust unit 300, also referred to herein as a “gas exhaust assembly,” may include an exhausting line 320 configured to discharge the process gas (including a by-product) from the process chamber 100, and a pump 340 configured to pump out the process gas and a control gas in the chamber. The exhausting line 320, also referred to herein as an exhausting gas “conduit,” may be referred to herein as a gas line, gas conduit, etc. The pump 340 may be configured to induce gas flow from the process chamber 100 through the exhausting line 320. The exhausting line 320 may be disposed to connect the process chamber 100 to the pump 340. An exhaust valve 350 may be provided at a first position P1 of the exhausting line 320. The exhaust valve 350 may be configured to control a flow rate of the process gas from the process chamber 100 into the exhausting line 320. For example, the exhaust valve 350 may be a throttle valve. In some embodiments, the exhaust valve 350 may be configured to be opened between about 7% of a fully-open position to about 20% of the fully-open position and the opening extent of the exhaust valve 350 may be fixed. A diffuser 370 may be provided at a second position P2 of the exhausting line 320. The second position P2 may be between the first position P1 and the pump 340. The exhausting line 320 may include an upper exhausting line 320a connecting the process chamber 100 with the diffuser 370 and a lower exhausting line 340a connecting the diffuser 370 with the pump 340. The diffuser 370 may be connected to the injection unit 400. The diffuser 370 may couple the injection unit 400 to the exhausting line 320, such that a control gas supplied by the injection unit 400 is supplied to the exhausting line 320 through the diffuser 370. The diffuser 370 may be configured to uniformly diffuse the control gas, if and/or when the control gas is supplied to the exhausting line 320 from the injection unit 400.

The pump 340 may be configured to perform a pumping operation for discharging the process and control gases from the exhausting line 320 to the outside of the exhausting line 320. An amount of the gas discharged by the pump 340 may be based on depending on a type of the gas.

The injection unit 400, also referred to herein as gas injector assembly, may be connected to the diffuser 370 and may be used to supply a third gas (i.e., control gas) into the exhausting line 320. In some example embodiments, the gas injector assembly may be referred to as a gas supply source. The third gas supplied by the injection unit 400 may be used to control an internal pressure of the process chamber 100. The injection unit 400 may include a third gas supplying part 420, also referred to herein as a third gas reservoir 420, in which the third gas is stored, and a third supplying line 440, which is used to supply the third gas to the process chamber 100. For example, the third gas may be one of non-reactive gases (e.g., argon (Ar), helium (He), or nitrogen (N₂)). A control valve 445 may be provided on the third supplying line 440 to control a flow rate of the third gas to be supplied to the process chamber 100.

The control unit 500, also referred to herein as the gas injection control device, may control the injection unit 400 to adjust a flow rate of the third gas to be supplied to the exhausting line 320. Information on an internal pressure of the process chamber 100 measured by the chamber pressure sensor 150 may be transmitted to the control unit 500, and the information may be used to calculate a compensation value for maintaining a desired (and/or alternatively predetermined) internal pressure of the process chamber 100. The desired (and/or alternatively predetermined) internal pressure of the process chamber 100 may range from 15 mTorr to 25 mTorr. The compensation value may be changed depending on kinds, flow rates, and pressures of the first and second gases. Based on the compensation value, the control unit 500 may control a flow rate of the third gas to be supplied from the third gas supplying part 420 and an extent of opening of the control valve 445.

The control unit 500 may include a controller device. The control unit 500 may include a processor 510 and a memory 520. The control unit 500 may include a controller device that includes one or more of a processor 510 and a memory 520. The memory 520 may be a nonvolatile memory, such as a flash memory, a phase-change random access memory (PRAM), a magneto-resistive RAM (MRAM), a resistive RAM (ReRAM), or a ferro-electric RAM (FRAM), or a volatile memory, such as a static RAM (SRAM), a dynamic RAM (DRAM), or a synchronous DRAM (SDRAM).

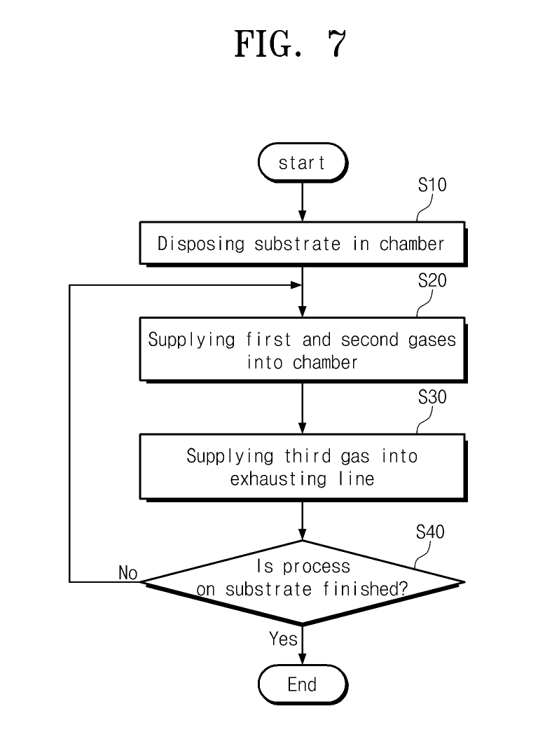

The processor 510 may be, a central processing unit (CPU), a controller, or an application-specific integrated circuit (ASIC), that when, executing instructions stored in the memory, configures the processor 510 as a special purpose computer to perform the operations of one or more portions of the control unit 500, the gas injector assembly 400, some combination thereof, or the like. For example, the control unit 500 may perform one or more of the operations illustrated in FIG. 7 such that the control unit 500 controls the supply of control gas to the gas exhaust assembly 300. The control unit 500 may improve the functioning of the substrate treatment apparatus 1 itself by improving the control of internal pressure of the process chamber 100, thereby improving the quality of treated substrates, the frequency at which substrate treatment processes are implemented, some combination thereof, or the like.

In some example embodiments, the processor 510 may be a hardware processor such as central processing unit (CPU), a multi-processor, a distributed processing system, an application specific integrated circuit (ASIC), and/or a suitable hardware processing unit.

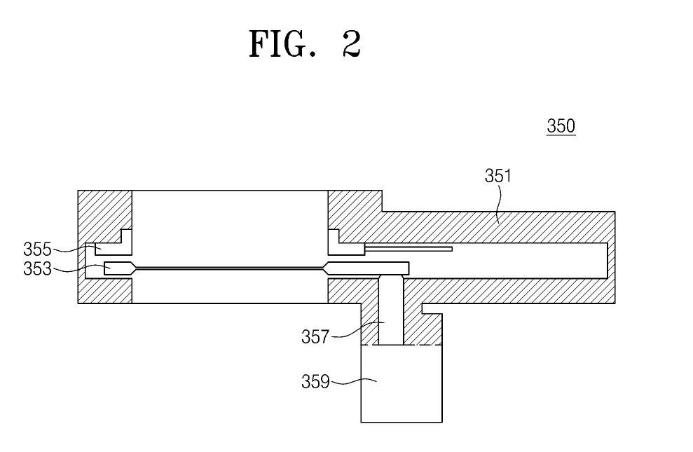

FIG. 2 is a cross-sectional view illustrating an exhaust valve according to some example embodiments of the inventive concepts.

Referring to FIGS. 1 and 2, the exhaust valve 350 may include a body portion 351, a plate 353, a sealing ring 355, a rotating axis 357, and a driving part 359. For example, the exhaust valve 350 may be a throttle valve. The body portion 351 may be connected to the exhausting line 320. The plate 353 and the sealing ring 355 may be provided to be in contact with each other and thereby to hermetically seal the exhausting line 320. For example, the plate 353 may be a circular disk shape, and the sealing ring 355 may be a ring shape. The plate 353 may be connected to the rotating axis 357 and may be movable in a horizontal direction, and the rotating axis 357 may be coupled to the body portion 351. The driving part 359 may be configured to adjust motion of the rotating axis 357. That is, motion of the plate 353 may be controlled by a driving force applied from the driving part 359 through the rotating axis 357.

In some example embodiments, an opening of the exhaust valve 350 may be controlled to adjust an amount of gas to be discharged through the exhausting line 320. By controlling an amount of gas to be exhausted through the exhausting line 320, it is possible to maintain an internal pressure of the process chamber 100 to a desired (and/or alternatively predetermined) level. However, since the exhaust valve 350 has a finite lifetime, as an operation of controlling the opening of the exhaust valve 350 is repeated over and over, a replacement period of the exhaust valve 350 may be decreased. According to some example embodiments of the inventive concepts, the exhaust valve 350 may be opened by 7% to 20% and the opening extent of the exhaust valve 350 may be fixed. Although the opening extent of the exhaust valve 350 is fixed, the internal pressure of the process chamber 100 may be controlled by adjusting a flow rate of the third gas to be supplied into the exhausting 320 from the injection unit 400. This may make it possible to prolong a replacement period of the exhaust valve 350.

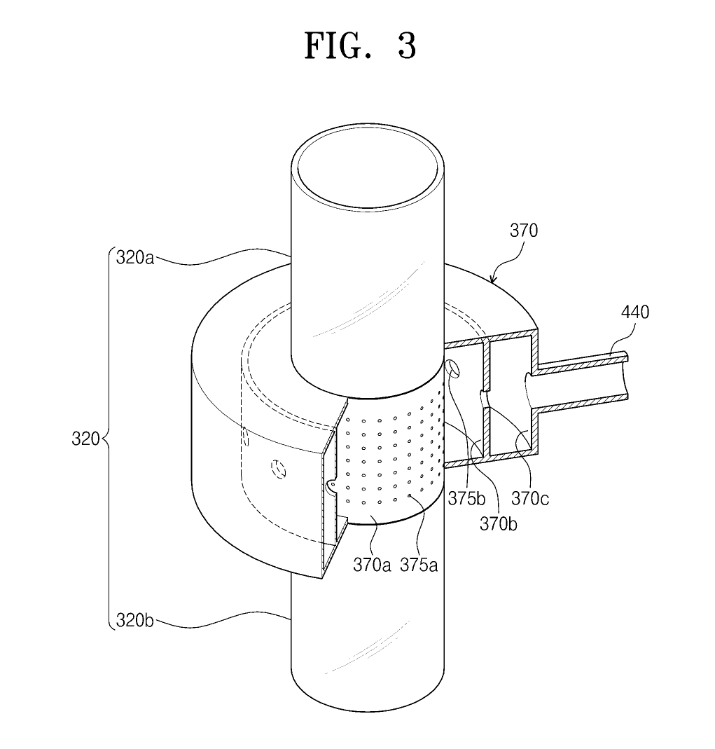

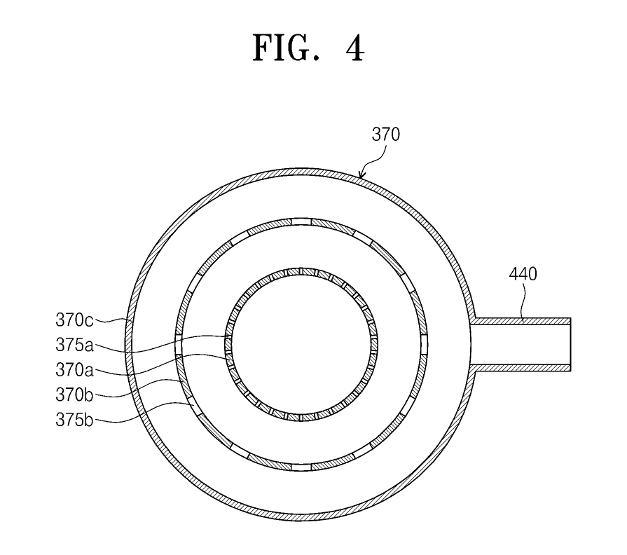

FIG. 3 is a partial perspective view illustrating a diffuser of FIG. 1, and FIG. 4 is a sectional view illustrating a diffuser of FIG. 1.

Referring to FIGS. 1, 3, and 4, the diffuser 370 may be provided between the upper exhausting line 320a and the lower exhausting line 320b. For example, the diffuser 370 may be a circular pipe shape. The diffuser 370 may include an inner part 370a, also referred to herein as an inner shell 370a, which is configured to allow the third gas, also referred to herein as a control gas, to be diffused into the exhausting line 320, a middle part 370b, also referred to herein as a middle shell 370b, which is configured to allow the third gas to be diffused into the inner part 370a, and an outer part 370c, also referred to herein as an outer shell 370c, which is configured to allow the third gas to be diffused into the middle part 370b. The inner part 370a may couple with one or more portions of the exhausting line 320. For example, the inner part 370a may be in direct contact with the upper exhausting line 320a and the lower exhausting line 320b. The inner part 370a may have a plurality of first holes 375a. The middle part 370b may have a diameter greater than that of the inner part 370a and may have a plurality of second holes 375b. The outer part 370c may be connected to the third supplying line 440, also referred to herein as a gas supply line 440, and may have a diameter greater than that of the middle part 370b. The first holes 375a may have a diameter smaller than that of the second holes 375b, and the number (“quantity”) of the first holes 375a may be greater than that of the second holes 375b. In the case where the third gas is supplied into the diffuser 370 through the third supplying line 440, the third gas may be diffused by the first holes 375a and the second holes 375b and may be supplied into the exhausting line 320.

In certain embodiments, the diffuser 370 may be configured to include a plurality of middle parts 370b between the inner part 370a and the outer part 370c. The increase in the number (“quantity”) of the middle parts 370b may make it possible to more easily diffuse the third gas, when the third gas is supplied into the exhausting line 320 from the third supplying line 440.

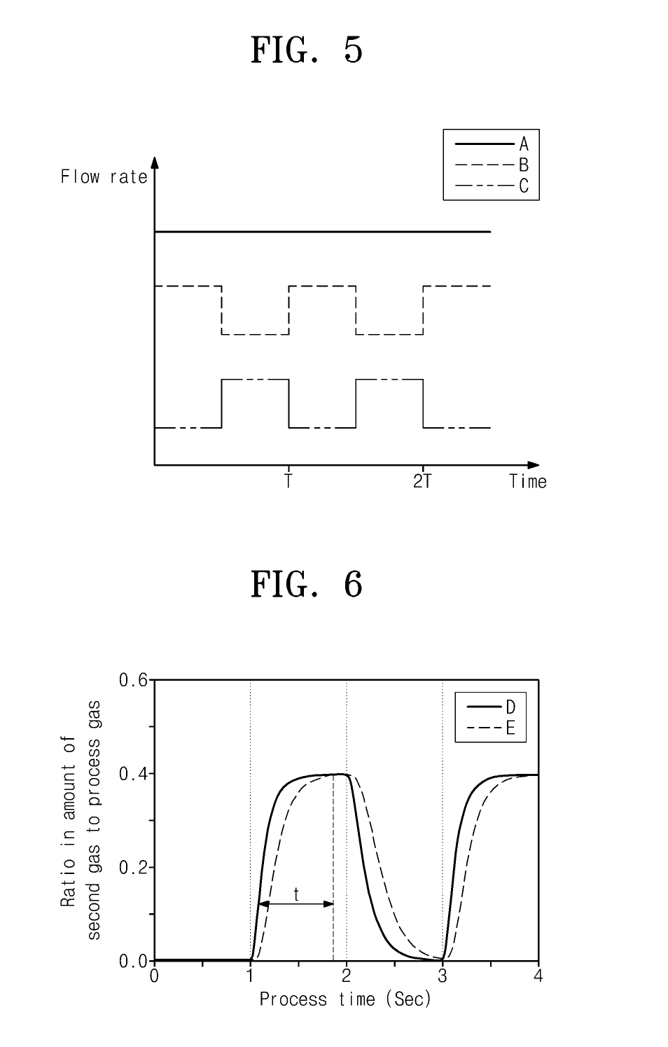

FIG. 5 is a graph showing a variation in flow rate of gases supplied into a chamber and an exhausting line, according to some example embodiments of the inventive concepts.

Referring to FIGS. 1 and 5, flow rates of the first, second, and third gases are depicted by lines A, B, and C, respectively. As depicted by the line A, the first gas may be supplied at a first flow rate that is uniform or substantially uniform, and as depicted by the line B, the second gas may be supplied at a second flow rate that is non-uniform. For example, as shown in FIG. 5, the second gas may be pulsed with a period of T, such that the second gas flow rate varies according to a pulse wave. In some example embodiments, including the example embodiments illustrated in FIG. 5, the second gas flow rate varies according to a square wave. The first gas and the second gas may be supplied into the process chamber 100. As depicted by the line C, the third gas may be supplied at a third flow rate that is pulsed with the period of T, such that the third gas flow rate varies according to a pulse wave. In the example embodiments illustrated in FIG. 5, the second gas flow rate varies according to a first square wave, and the third gas flow rate varies according to a second square wave. The pulsating period T in flow rate of the second and third gases may be the same time period. The third gas may be supplied into the exhausting line 320. The flow rates of the second and third gases may be changed to form a rectangular pulse shape, and the pulsating period T may range from 3 seconds to 5 seconds.

An internal pressure of the process chamber 100 may be maintained to a desired (and/or alternatively predetermined) level ranging from about 15 mTorr to about 25 mTorr. Information on an internal pressure of the process chamber 100 measured by the chamber pressure sensor 150 may be transmitted to the control unit 500, and the information may be used by the control unit 500 to calculate a compensation value for maintaining a desired (and/or alternatively predetermined) internal pressure of the process chamber 100. The compensation value may be changed depending on kinds (“types”), flow rates, and pressures of one or more of the first and second gases. Information identifying a type of one or more of the first and second gasses may be stored at a memory 520 included in the control unit 500. The control unit 500 may access the information from the memory 520 as part of calculating the compensation value. Based on the compensation value, the control unit 500 may adjustably control the third gas supplying part 420 and the control valve 445 of the injection unit 400 to adjustably control the supply of the third gas into the exhausting line 320. In some example embodiments, the supply of third gas may be adjustably controlled such that the flow rate of the third gas into the gas exhaust assembly 300 varies according to a pulse wave, square wave, some combination thereof, or the like. In some example embodiments, the third gas flow rate varies according to a wave that is phase-shifted from a wave according to which the second gas flow rate varies (e.g., by a phase difference of half the period T). In some example embodiments, the third gas flow rate varies according to a wave that is phase shifted from the wave according to which the second gas flow rate varies by about 180 degrees. In other words, if and/or when the second flow rate is at a maximum, the third flow rate may be at a minimum, and if and/or when the second flow rate is at a minimum, the third flow rate may be at a maximum.

If and/or when the second flow rate varies according to a pulse wave (e.g., changes in a pulsed manner), internal pressures of the process chamber 100 and the exhausting line 320 may be unsteady. By supplying the third gas, whose flow rate may vary according to a wave that is phase-shifted by the phase difference of T/2 from the wave according to which the flow rate of the second gas varies, into the exhausting line 320, it may be possible to reduce and/or prevent the unsteadiness in internal pressure of the process chamber 100 and the exhausting line 320, such that the internal pressure of the process chamber 100 is uniform or substantially uniform. Since all of the first, second, and third gases are pumped out by the pump 340 and an amount of gas to be pumped out by the pump 340 may be maintained at a desired (and/or alternatively predetermined) level, it may be possible to uniformly or substantially uniformly maintain an amount of gas to be discharged from the process chamber 100 through the exhausting line 320 and/or a flow rate of gas that is exhausted from the process chamber 100 through the exhausting line 320. Accordingly, an internal pressure of the process chamber 100 may be stabilized at a desired (and/or alternatively predetermined) level.

FIG. 6 is a graph showing the times taken to stabilize internal pressures of a chamber and an exhausting line, according to some example embodiments of the inventive concepts.

Referring to FIGS. 1 and 6, an x-axis represents a process time, and a y-axis represents a ratio in amount of the second gas to the process gas. A solid line D illustrates a ratio in amount of the second gas to the process gas in the process chamber 100, and a dotted line E illustrates a ratio in amount of the second gas to the process gas in the exhaust valve 350.

According to some example embodiments of the inventive concepts, by adjusting a pressure of the exhausting line 320 where the exhausting line 320 has a relatively small volume, it may be possible to control an internal pressure of the process chamber 100 where the process chamber 100 has a relatively large volume. In detail, if and/or when a process starts, a process gas may be supplied into the process chamber 100. Here, the control gas (e.g., the third gas) may be supplied into the exhausting line 320 from the injection unit 400 to cancel a change in the pressure of the process chamber 100 and the exhausting line 320, which may be caused by the second gas to be supplied into the process chamber 100. In some embodiments, the ratio of the second gas to the process gas in the process chamber 100 may become the same as that in the exhaust valve 350, within a second from the start of the process. Since the process chamber 100 and the exhaust valve 350 have the same ratio of the second gas to the process gas, an amount of the process gas to be exhausted from the process chamber 100 to the exhausting line 320 may be uniform or substantially uniform. This means that an internal pressure of the process chamber 100 may be stabilized or substantially stabilized. It is possible to reliably execute the process, because the supply of the third gas into the exhausting line 320 makes it possible to stabilize the internal pressure of the process chamber 100 within a second.

FIG. 7 is a flow chart illustrating a method of controlling an internal pressure of a chamber, according to some example embodiments of the inventive concepts. In some example embodiments, the method illustrated in FIG. 7 may be implemented by one or more portions of the control unit 500, including the processor 510.

Referring to FIGS. 1, 5, 6, and 7, a process of treating a substrate may include steps of disposing the substrate S in the process chamber 100 (in S10), supplying the first gas and the second gas into the process chamber 100 (in S20), supplying the third gas into the exhausting line 320 (in S30), and examining whether the process on the substrate is finished (in S40).

In step S10 of disposing the substrate S into the process chamber 100, the substrate S may be loaded on the electrostatic chuck 110 of the process chamber 100. When the substrate S is disposed in the process chamber 100, a process of treating the substrate S may start. In step S20 of supplying the first gas and the second gas into the process chamber 100, the first and second gases for treating the substrate S may be supplied into the process chamber 100. The first gas may be supplied at a first flow rate that is uniform or substantially uniform, and the second gas may be supplied at a non-uniform second flow rate that is pulsed with a period of T (e.g., varies according to a pulse wave having a period of a time period “T”). In step S30 of supplying the third gas into the exhausting line 320, the third gas may be supplied into the exhausting line 320 through the injection unit 400. A flow rate of the process gas to be discharged from the process chamber 100 to the exhausting line 320 may be controlled by adjustably controlling the supply of the third gas into the exhausting line 320. This may make it possible to quickly stabilize an internal pressure of the process chamber 100 to a desired (and/or alternatively predetermined) level. The steps S20 and S30 may be repeated until the treatment process on the substrate is finished.

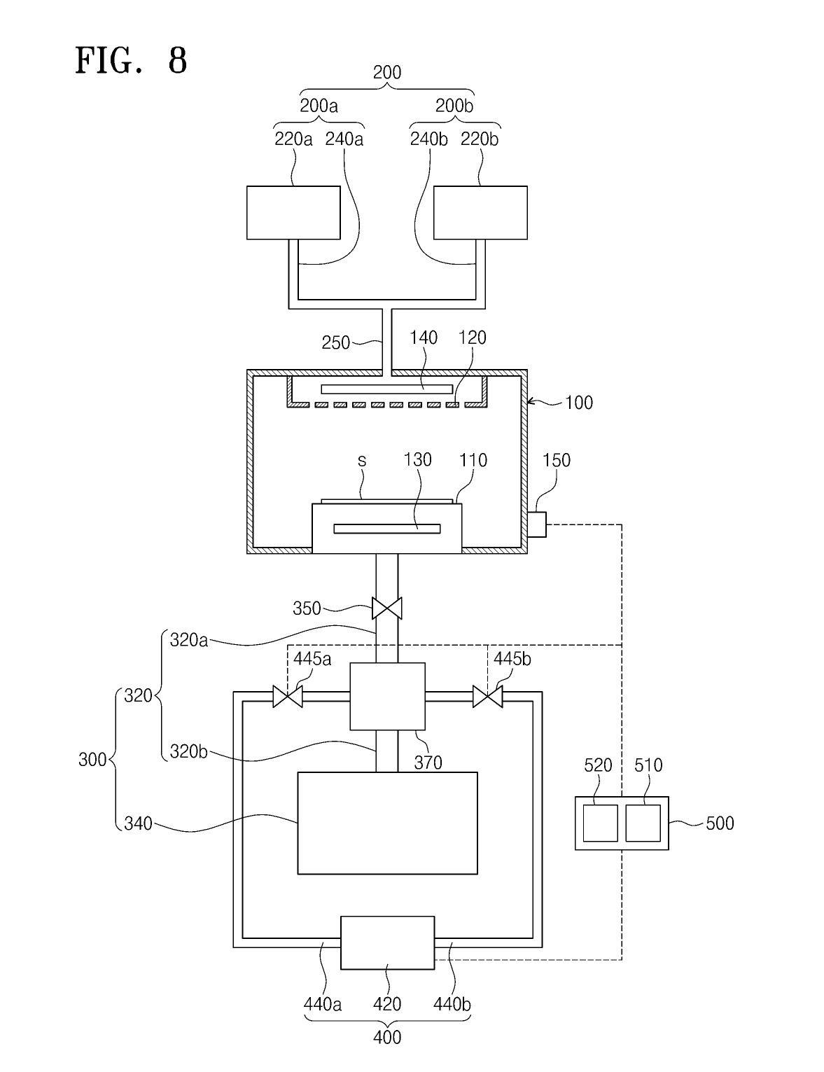

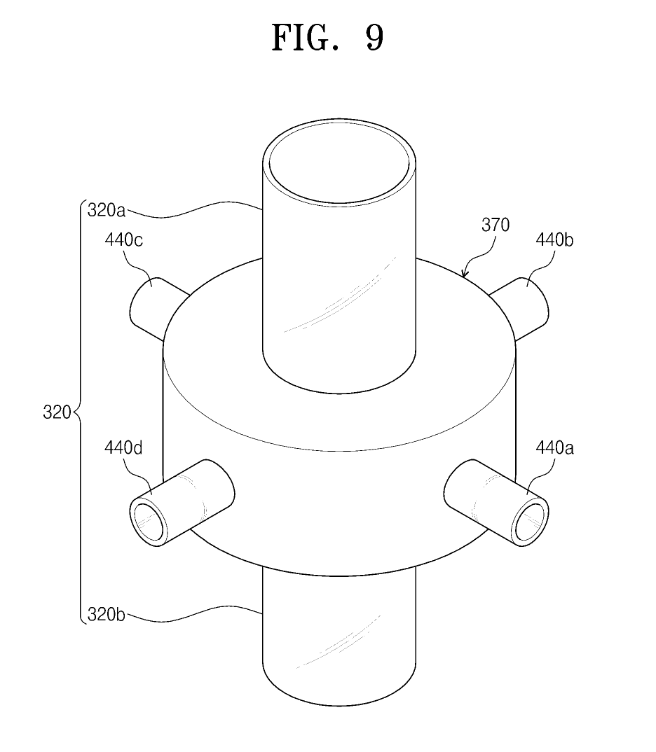

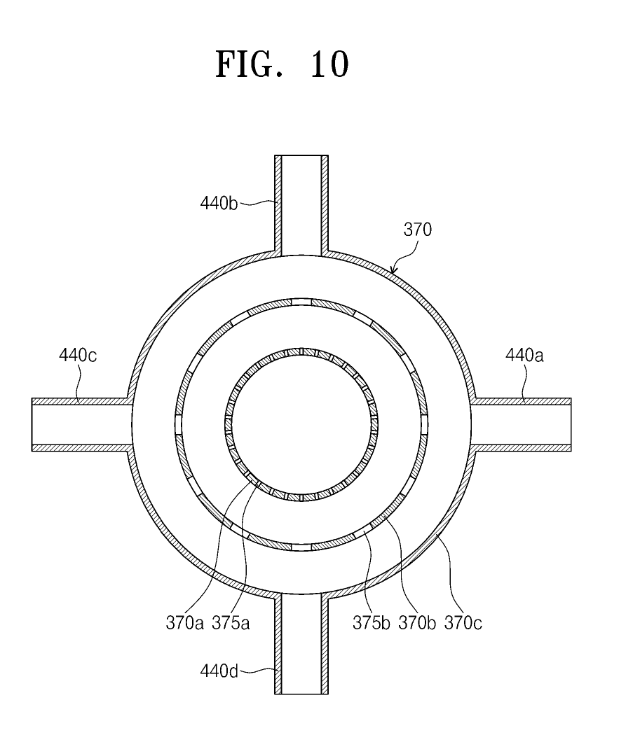

FIG. 8 is a diagram schematically illustrating a substrate treatment apparatus according to some example embodiments of the inventive concepts, FIG. 9 is a perspective view illustrating a diffuser of FIG. 8, and FIG. 10 is a sectional view illustrating a diffuser of FIG. 8. For concise description, a previously described element may be identified by a similar or identical reference number without repeating an overlapping description thereof.

Referring to FIGS. 8-10, a substrate treatment apparatus 2 may include the process chamber 100, the supplying unit 200, the exhaust unit 300, the injection unit 400, and the control unit 500. The supplying unit 200 may include the first supplying unit 200a, the second supplying unit 200b, and the main line 250. The first supplying unit 200a may include the first gas supplying part 220a, in which the first gas is stored, and the first supplying line 240a, which is used to supply the first gas from the first gas supplying part 220a to the process chamber 100. The second the supplying unit 200b may include the second gas supplying part 220b, in which the second gas is stored, and the second supplying line 240b, which is used to supply the second gas from the second gas supplying part 220b to the process chamber 100. The exhaust unit 300 may include the exhausting line 320, which is connected between the process chamber 100 and the pump 340, and the pump 340, which is configured to pump out a process gas from the process chamber 100. The exhaust valve 350 and the diffuser 370 may be provided on the exhausting line 320.

The injection unit 400 may be connected to the diffuser 370 and may be used to supply the third gas into the exhausting line 320. The injection unit 400 may include the third gas supplying part 420, in which the third gas is stored, and third supplying lines (also referred to herein as gas supply lines) 440a, 440b, 440c, and 440d, which are configured to supply the third gas into the exhaust unit 300. The third supplying lines 440a, 440b, 440c, and 440d may be symmetrically disposed about and connected to the diffuser 370. In some embodiments, the third supplying lines 440a, 440b, 440c, and 440d may be spaced apart from each other by a uniform distance. The injection unit 400 may be configured to supply the third gas into the exhausting line 320, and this may make it possible to control an internal pressure of the process chamber 100. For example, the third gas may be one of non-reactive gases (e.g., argon (Ar), helium (He), or nitrogen (N2)). Control valves 445a and 445b may be provided on the third supplying lines 440a, 440b, 440c, and 440d to adjust a flow rate of the third gas to be supplied to the process chamber 100. The control valves 445a and 445b may control an extent of opening of each of the third supplying lines 440a, 440b, 440c, and 440d, based on a compensation value obtained by the control unit 500.

The control unit 500 may control the injection unit 400 to adjust a flow rate of the third gas to be supplied to the exhausting line 320. Information on an internal pressure of the process chamber 100 measured by the chamber pressure sensor 150 may be transmitted to the control unit 500, and the information may be used to calculate a compensation value for maintaining a desired (and/or alternatively predetermined) internal pressure of the process chamber 100. The desired (and/or alternatively predetermined) internal pressure of the process chamber 100 may range from 15 mTorr to 25 mTorr. The compensation value may be changed depending on kinds, flow rates, and pressures of the first and second gases. The control unit 500 may control the third gas supplying part 420 and the control valves 445a and 445b of the injection unit 400, based on the compensation value.

Since a plurality of lines (e.g., the third supplying lines 440a, 440b, 440c, and 440d) are connected to the exhausting line 320, it is possible to reduce and/or prevent a pressure of the third gas from being abruptly changed when the third gas is supplied into the exhausting line 320. The control valves 445a and 445b may make it possible to minutely adjust a flow rate of the third gas passing through each of the third supplying lines 440a, 440b, 440c, and 440d.

In certain embodiments, the first holes 375a may have a diameter that is equal to or greater than that of the second holes 375b. The number of the number of the third supplying lines 440 connected to the diffuser 370 may not be limited to that of the above-described embodiments.

According to some example embodiments of the inventive concepts, by supplying an addition gas into an exhausting line, it is possible to control an internal pressure of a chamber.

According to some example embodiments of the inventive concepts, a diffuser may be provided on the exhausting line to diffuse gas when the gas is supplied into the exhausting line through an injection unit.

According to some example embodiments of the inventive concepts, the additional gas is supplied into the exhausting line in such a way that a flow rate thereof is different, by a phase difference of half period, from that of a gas to be supplied into the chamber, and this may make it possible to maintain the internal pressure of the chamber to a desired (and/or alternatively predetermined) level.

Units and/or devices according to one or more example embodiments may be implemented using hardware, software, and/or a combination thereof. For example, hardware devices may be implemented using processing circuitry such as, but not limited to, a processor, Central Processing Unit (CPU), a controller, an arithmetic logic unit (ALU), a digital signal processor, a microcomputer, a field programmable gate array (FPGA), a System-on-Chip (SoC), an application-specific integrated circuit (ASIC), a programmable logic unit, a microprocessor, or any other device capable of responding to and executing instructions in a defined manner.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as one computer processing device; however, one skilled in the art will appreciate that a hardware device may include multiple processing elements and multiple types of processing elements. For example, a hardware device may include multiple processors or a processor and a controller. In addition, other processing configurations are possible, such as parallel processors.

It should be understood that example embodiments described herein should be considered in a descriptive sense only and not for purposes of limitation. Descriptions of features or aspects within each device or method according to example embodiments should typically be considered as available for other similar features or aspects in other devices or methods according to example embodiments. While some example embodiments have been particularly shown and described, it will be understood by one of ordinary skill in the art that variations in form and detail may be made therein without departing from the spirit and scope of the claims.

What is claimed is:

1. A substrate treatment apparatus, comprising:
a process chamber;
a gas supply assembly configured to supply a first gas and a second gas into the process chamber such that,
the first gas is supplied into the process chamber at a uniform first flow rate, and
the second gas is supplied into the process chamber at a second flow rate, the second flow rate varying according to a first pulse wave, the first pulse wave having a particular time period;
a gas exhaust assembly configured to exhaust the first and second gases from the process chamber, the gas exhaust assembly including,
an exhausting line coupled to the process chamber, the exhausting line being configured to discharge gas from the process chamber, and
a pump coupled to the exhausting line, the pump being configured to induce gas flow from the process chamber through the exhausting line;
an exhaust valve coupled to the exhausting line, the exhaust valve being configured to control a flow rate of gas into the exhausting line from the process chamber, the exhaust valve including a fixed opening extent; and
a gas injector assembly coupled to the exhausting line between the exhaust valve and the pump, the gas injector assembly being configured to supply a third gas into the exhausting line; and
a gas injection control device configured to,
measure an internal pressure of the process chamber, and
control the injection unit to supply the third gas into the exhausting line at a third flow rate based on the measured internal pressure of the process chamber, the third flow rate varying according to a second pulse wave, the second pulse wave having the particular time period.

2. The apparatus of claim 1, wherein the gas injection control device includes,
a chamber pressure sensor configured to measure the internal pressure of the process chamber; and
a controller device configured to
process the measured internal pressure of the process chamber to determine the third flow rate, and
control the injection unit to supply the third gas into the exhausting line according to the third flow rate.

3. The apparatus of claim 1, wherein the second pulse wave is phase-shifted from the first pulse wave according to a phase difference, the phase difference being approximately one-half of the time period.

4. The apparatus of claim 3, wherein
the second pulse wave is phase-shifted from the first pulse wave by approximately 180 degrees.

5. The apparatus of claim 1, wherein the gas injection control device is configured to control the third flow rate such that the internal pressure of the process chamber ranges from about 15 mTorr to about 25 mTorr.

6. The apparatus of claim 1, wherein
the gas injector assembly includes,
a third gas reservoir configured to hold the third gas, and
a third gas supply line that couples the third gas reservoir to the exhausting line;
the apparatus further includes a control valve coupled to the third gas supply line, the control valve being configured to control an opening extent of the third gas supply line; and
the gas injection control device is configured to control the third gas reservoir and the control valve to adjustably control the third flow rate.

7. The apparatus of claim 1, wherein
the first gas includes one of argon or helium,
the second gas includes one or more fluorocarbons, and
the third gas is a non-reactive gas including one of argon, nitrogen, or helium.

8. The apparatus of claim 1, further comprising:
a diffuser between the exhausting line and the gas injector assembly, the diffuser being configured to diffuse the third gas supplied into the exhausting line from the gas injector assembly.

9. A substrate treatment apparatus, comprising:
a process chamber;
a gas supply assembly configured to supply a first gas and a second gas into the process chamber;
a gas exhaust assembly configured to exhaust the first and second gases from the process chamber, the gas exhaust assembly including
an exhausting line coupled to the process chamber, the exhausting line being configured to discharge gas from the process chamber, and
a pump coupled to the exhausting line, the pump being configured to induce gas flow from the process chamber through the exhausting line;
an exhaust valve coupled to the exhausting line, the exhaust valve being configured to control a flow rate of gas into the exhausting line from the process chamber, the exhaust valve including a fixed opening extent; and
a gas injector assembly coupled to the exhausting line between the exhaust valve and the pump, the gas injector assembly being configured to supply a third gas into the exhausting line; and
a diffuser configured to diffuse the third gas supplied into the exhausting line from the gas injector assembly.

10. The apparatus of claim 9, wherein the diffuser includes,
an outer shell coupled to the gas injector assembly; and
an inner shell, the inner shell having a smaller diameter than the outer shell, the inner shell including a plurality of first holes, the inner shell being configured to diffuse the third gas into the exhausting line through the plurality of first holes.

11. The apparatus of claim 9, wherein the diffuser further includes a middle shell between the outer shell and the inner shell, the middle shell including a plurality of second holes.

12. The apparatus of claim 11, wherein a quantity of the first holes is greater than a quantity of the second holes.

13. The apparatus of claim 11, wherein each of the second holes includes a greater diameter than the first holes.

14. The apparatus of claim 9, further comprising:
a plurality of gas injector assemblies, the gas injector assemblies being spaced apart according to a uniform distance.

15. The apparatus of claim 9, wherein the exhaust valve is configured to be opened between about 7% of a fully-open position to about 20% of the fully-open position.

16. An apparatus, comprising:
a diffuser configured to couple to a gas line and diffuse a gas into the gas line, the diffuser including,
an outer shell including at least one gas supply line, the outer shell being configured to couple with a gas supply source through the at least one gas supply line; and
an inner shell at least partially enclosed by the outer shell, the inner shell being configured to couple with the gas line, the inner shell including a plurality of first holes, the inner shell being configured to diffuse the gas into the exhausting line through the plurality of first holes.

17. The apparatus of claim 16, wherein the diffuser further includes a middle shell between the outer shell and the inner shell, the middle shell including a plurality of second holes.

18. The apparatus of claim 17, wherein a quantity of the first holes is greater than a quantity of the second holes.

19. The apparatus of claim 17, wherein each of the second holes includes a greater diameter than the first holes.

20. The apparatus of claim 16, wherein the outer shell includes a plurality of gas supply lines, the outer shell being configured to couple with at least one gas supply source through the plurality of gas supply lines.
